(19) United States
(12) Patent Application Publication
(10) Pub. No.: US 2020/0312674 A1
(43) Pub. Date: Oct. 1, 2020

(54) METHOD OF MANUFACTURING AN INTERPOSER AND A METHOD OF MANUFACTURING A SEMICONDUCTOR PACKAGE INCLUDING THE SAME

(71) Applicant: SAMSUNG ELECTRONICS CO., LTD., Suwon-Si (KR)

(72) Inventors: SUNG-WOO PARK, SEONGNAM-SI (KR); UNG-CHEON KIM, SEOUL (KR); YU-KYUNG PARK, HWASEONG-SI (KR); SEUNG-KWAN RYU, SEONGNAM-SI (KR)

(21) Appl. No.: 16/582,763

(22) Filed: Sep. 25, 2019

(30) Foreign Application Priority Data
Mar. 26, 2019 (KR) 10-2019-0034482

(51) Int. Cl. H01L 21/48; H01L 21/56

(52) U.S. Cl. CPC H01L 21/486; H01L 21/4871; H01L 21/565; H01L 21/4853

(57) ABSTRACT

A method for manufacturing an interposer provides for disposing a lower insulating layer on a second surface opposite to a first surface of an interposer substrate. A first alignment key on the first surface is aligned with a first photomask. The lower insulating layer is patterned with the first photomask to form a lower circuit pattern and a second alignment key on the second surface. A lower metal layer is formed on the lower insulating layer. The second alignment key is aligned with a second photomask and a photoresist layer is patterned on the lower metal layer to expose the lower circuit pattern using the second photomask.

### CROSS-REFERENCE TO RELATED APPLICATION

This application claims the benefit of priority under 35 § 119 to Korean Patent Application No. 10-2019-0034482, filed on Nov. 26, 2019, in the Korean Intellectual Property Office, the disclosure of which is incorporated by reference herein in its entirety.

### TECHNICAL FIELD

The present inventive concept relates to a method of manufacturing an interposer and a method of manufacturing a semiconductor package including the same.

### DISCUSSION OF RELATED ART

A printed circuit board (PCB) is limited in its ability to accommodate a highly integrated semiconductor. To solve this dilemma, a semiconductor package structure in which an interposer is disposed between a semiconductor chip and a package substrate has been used. However, an interposer manufacturing process is costly and complicated. Many issues remain to be solved for economical and simple interposer mass production. When a rewiring layer process is performed on a back side of the interposer, an alignment key on a front side thereof may not be observed due to a seed metal layer used to perform the rewiring layer process. Accordingly, a separate alignment key on the back side is necessary.

### SUMMARY

The present inventive concept provides for a method of manufacturing an interposer, capable of saving manufacturing costs by simplifying a manufacturing process of the interposer.

The inventive concept also provides for a method of manufacturing a semiconductor package, capable of mounting an interposer on a circuit bond by easily aligning the interposer with the circuit board.

A method for manufacturing an interposer provides for disposing a lower insulating layer on a second surface opposite to a first surface of an interposer substrate. A first alignment key on the first surface is aligned with a first photomask. The lower insulating layer is patterned with the first photomask to form a lower circuit pattern and a second alignment key on the second surface. A lower metal layer is formed on the lower insulating layer. The second alignment key is aligned with a second photomask and a photoresist layer is patterned on the lower metal layer to expose the lower circuit pattern using the second photomask.

According to an exemplary embodiment of the present inventive concept, a method of manufacturing an interposer is provided including forming a through silicon via (TSV) in an interposer substrate. An upper insulating layer is disposed on a first surface of the interposer substrate. An upper circuit pattern and a first alignment key are formed by patterning the upper insulating layer. An upper metal layer is disposed on the upper insulating layer. A conductive pattern is disposed on the upper metal layer. A lower insulating layer is disposed on the second surface. The first alignment key is aligned with a first photomask and the lower insulating layer is patterned to form a lower circuit pattern and a second alignment key on the second surface. A lower metal layer is formed on the lower insulating layer. The second alignment key is aligned with a second photomask. A photoresist layer is patterned on the lower metal layer to expose the lower circuit pattern and a connection terminal is formed on the lower circuit pattern.

According to an exemplary embodiment of the present inventive concept, a method of manufacturing a semiconductor package is provided including manufacturing an interposer. The interposer is mounted on a circuit board. A semiconductor chip is mounted on the interposer; and an encapsulation material is formed for molding the interposer and the semiconductor chip. The manufacturing of the interposer includes disposing a lower insulating layer on a second surface opposite to a first surface of an interposer substrate. A first alignment key is aligned on the first surface with a first photomask. The lower insulating layer is patterned to form a lower circuit pattern and a second alignment key on the second surface. A lower metal layer is formed on the lower insulating layer. The second alignment key is aligned with a second photomask and patterning a photoresist layer on the lower metal layer to expose the lower circuit pattern using the second photomask.

According to an exemplary embodiment of the present inventive concept, a method of manufacturing an interposer includes providing an interposer substrate including a first surface with a first alignment key opposite to a second surface with an insulating layer. The insulating layer is patterned with a first photomask to form a circuit pattern and a second alignment key. A metal layer is disposed on the patterned insulating layer. The second alignment key at the second surface is aligned with an alignment key of a second photomask before patterning a photoresist layer on the metal layer and the first and second alignment keys overlap a cutting line of a scribe lane.

### BRIEF DESCRIPTION OF THE DRAWINGS

The above and other features of the present inventive concept will become more apparent with reference to the following Detailed Description when considered in conjunction with the attached drawings in which:

FIG. 1 is a cross-sectional view illustrating an interposer according to an exemplary embodiment of the present inventive concept;

FIG. 2 is a top view illustrating an interposer substrate according to an exemplary embodiment of the present inventive concept;

FIGS. 3 to 6 are cross-sectional views illustrating operations of forming a through silicon via (TSV) in the interposer substrate, according to an exemplary embodiment of the present inventive concept;

FIGS. 7 to 13 are cross-sectional views illustrating operations of forming components of the interposer on a first surface of the interposer substrate, according to an exemplary embodiment of the present inventive concept;

FIGS. 14 to 16 are cross-sectional views illustrating operations of exposing the TSV on a second surface of the interposer substrate and etching a portion of the TSV, according to an exemplary embodiment of the present inventive concept;

FIG. 17 is a flowchart illustrating operations of forming components of the interposer on the second surface of the interposer substrate, according to an exemplary embodiment of the present inventive concept;

FIGS. 18 to 27 are top views and cross-sectional views illustrating operations of forming components of the interposer on the second surface of the interposer substrate, according to an exemplary embodiment of the present inventive concept;

FIG. 28 is a cross-sectional view illustrating an operation of cutting the interposer substrate, according to an exemplary embodiment of the present inventive concept;

FIG. 29 is a flowchart illustrating a method of manufacturing a semiconductor package including the interposer, according to an exemplary embodiment of the present inventive concept; and

FIGS. 30 to 33 are cross-sectional views illustrating operations of the method of manufacturing the semiconductor package including the interposer, according to an exemplary embodiment of the present inventive concept.

### DETAILED DESCRIPTION OF THE EMBODIMENTS

Hereinafter, exemplary embodiments of the present inventive concept will be described in detail with reference to the accompanying drawings.

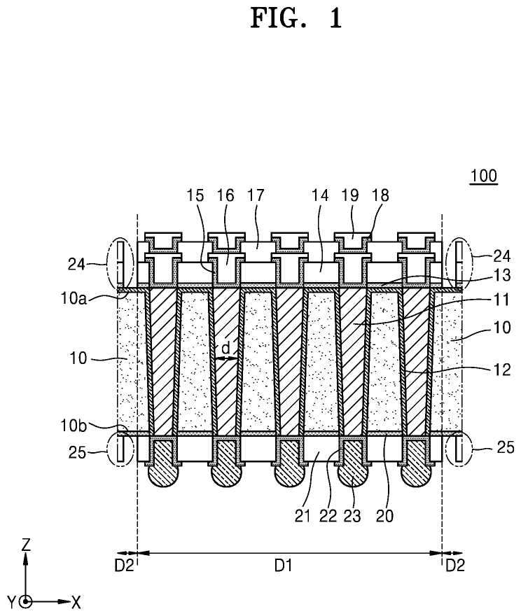

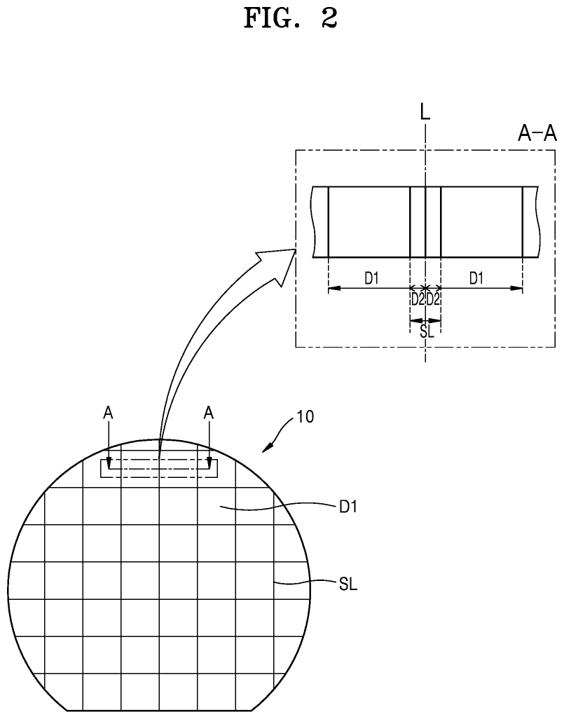

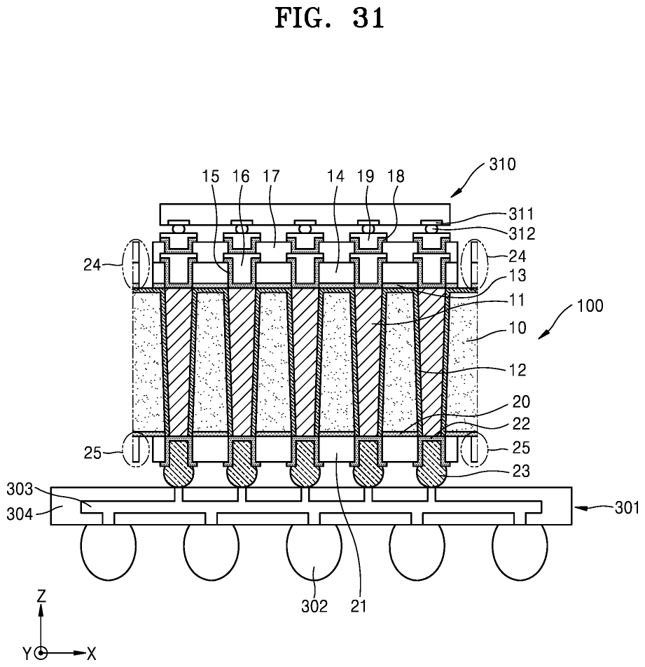

FIG. 1 is a cross-sectional view of an interposer 100 according to an exemplary embodiment of the present inventive concept. The interposer 100 according to an exemplary embodiment of the present inventive concept may include a mounting area D1 and a residual area D2. The mounting area D1 may be an area on which components of the interposer 100 are formed, and a semiconductor chip, to be described below (see 310 of FIG. 31), is mounted. The residual area D2 may refer to at least one area of a scribe lane (SL of FIG. 2) of an interposer substrate 10, which remains after an individualization operation of the interposer 100.

According to an exemplary embodiment of the present inventive concept, the interposer 100 may include, in the mounting area D1: the interposer substrate 10, a through silicon via (TSV) 11, an insulating layer 12, an etch stopping layer 13, a first upper insulating layer 14, a first upper metal layer 15, a first conductive pattern 16, a second upper insulating layer 17, a second upper metal layer 18, a second conductive pattern 19, a protective layer 20, a lower insulating layer 21, a lower metal layer 22, and a connection terminal 23. In addition, the interposer 100 may include a first alignment key 24 and a second alignment key 25 in the residual area D2.

According to an exemplary embodiment of the present inventive concept, the interposer substrate 10 may include a first surface 10a and a second surface 10b opposite to the first surface 10a. The interposer substrate 10 may support components formed on the first surface 10a and the second surface 10b. The interposer substrate 10 may include silicon (Si). However, the interposer substrate 10 is not limited thereto and may include a semiconductor element such as germanium (Ge) and/or include a semiconductor compound such as silicon carbide (SiC), gallium arsenide (GaAs), indium arsenide (InAs), and/or indium phosphide (InP).

According to an exemplary embodiment of the present inventive concept, the TSV 11 may be formed by defining a hole penetrating through the interposer substrate 10. The TSV 11 may penetrate the interposer substrate 10 and be exposed on the first surface 10a and the second surface 10b. The TSV 11 may be connected to the first upper metal layer 15 formed on the first surface 10a and the lower metal layer 22 formed on the second surface 10b.

As shown in FIG. 1, the TSV 11 may have a tapered shape having a cross-sectional area gradually decreasing downward from the first surface 10a of the interposer substrate 10 toward the second surface 10b. For example, a width d of the TSV 11 in a first direction (e.g., an X direction) may decrease downward from the first surface 10a. However, the TSV 11 is not limited thereto, and the width d of the TSV 11 in the first direction (e.g., the X direction) may be substantially identical from the first surface 10a to the second surface 10b. For example, the TSV 11 may have a cylindrical shape or a rectangular parallelepiped shape.

According to an exemplary embodiment of the present inventive concept, the TSV 11 may have a structure in which a seed layer and a conductive layer are sequentially formed. The conductive layer may include conductive materials, and the conductive layer may include, for example, a metal material. According to an exemplary embodiment of the present inventive concept, the conductive layer may include aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and/or zirconium (Zr).

According to an exemplary embodiment of the present inventive concept, the insulating layer 12 may electrically insulate the TSV 11 from the interposer substrate 10. As shown in FIG. 1, the insulating layer 12 may be formed along the first surface 10a and between an inner side surface of the interposer substrate 10 and a side surface of the TSV 11. The insulating layer 12 may cover only a portion of the first surface 10a of the interposer substrate 10 (e.g., a portion of the first surface 10a between adjacent TSV 11) and might not overlap an upper surface of the TSV 11 that is exposed through the first surface 10a. Thus the first upper metal layer 15 may be formed on the portion of the TSV 11 that is exposed through a first surface 10a and electrically connect to the TSV 11.

The insulating layer 12 may include an oxide, a nitride, and/or an oxynitride, for example, a silicon oxide, a silicon nitride, or a silicon oxynitride. According to an exemplary embodiment of the present inventive concept, the etch stopping layer 13 may be disposed on the insulating layer 12 of the interposer substrate 10. In addition, the etch stopping layer 13 may not cover the upper surface of the TSV 11. The etch stopping layer 13 may include a silicon oxide, a silicon nitride, a silicon oxynitride, and/or silicon carbide. A material of the etch stopping layer 13 may differ from a material of the insulating layer 12.

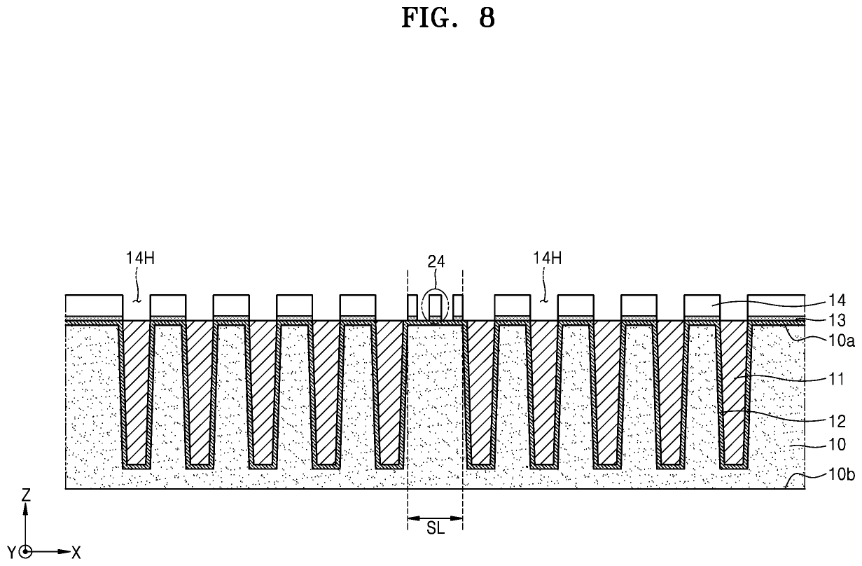

According to an exemplary embodiment of the present inventive concept, the first upper insulating layer 14 may be disposed on the first surface 10a of the interposer substrate 10. For example, the first upper insulating layer 14 may be disposed on the etch stopping layer 13. The first upper insulating layer 14 may include an oxide, a nitride, and/or an oxynitride, for example, a silicon oxide, a silicon nitride, and/or a silicon oxynitride. The first upper insulating layer 14 may have a first opening (14H shown in FIG. 8) to be formed through a photolithography process to be described below. The first opening 14H may expose the TSV 11 through the first surface 10a of the interposer substrate 10. The first upper metal layer 15 and the first conductive pattern 16 to be described below may be sequentially stacked on the first opening 14H formed in the first upper insulating layer 14.

According to an exemplary embodiment of the present inventive concept, the first upper metal layer 15 may be disposed on an inner side surface and at least a portion of an upper surface of the first upper insulating layer 14, and the upper surface of the TSV 11. The first upper metal layer 15 may come in contact with the upper surface of the TSV 11 exposed through the first surface 10a and electrically connect to the TSV 11. According to an exemplary embodiment of the present inventive concept, the first upper metal layer 15 may have a structure in which a plurality of metal layers are stacked. The stacked number and a material of the plurality of metal layers may be variously changed. For example, the first upper metal layer 15 may have a structure in which a Cu metal layer is stacked on a Ti metal layer.

According to an exemplary embodiment of the present inventive concept, the first conductive pattern 16 may be a re-wiring pattern filling the first opening 14H formed in the first upper insulating layer 14. The first conductive pattern 16 may include a metal having high electrical conductivity, and for example, the first conductive pattern 16 may include Cu. The first conductive pattern 16 may come in contact with the first upper metal layer 15, and accordingly, the first conductive pattern 16 may be electrically connected to the TSV 11.

According to an exemplary embodiment of the present inventive concept, the second upper insulating layer 17 may be disposed on the first upper insulating layer 14. For example, the second upper insulating layer 17 may be disposed on the upper surface of the first upper insulating layer 14 and at least a portion of an upper surface of the first conductive pattern 16. The second upper insulating layer 17 may include an oxide, a nitride, and/or oxynitride, for example, a silicon oxide, a silicon nitride, and/or a silicon oxynitride. A material of the second upper insulating layer 17 may be substantially the same as a material of the first upper insulating layer 14. However, the second upper insulating layer 17 is not limited thereto, and the material of the second upper insulating layer 17 may differ from the material of the first upper insulating layer 14. The second upper insulating layer 17 may have a second opening formed to expose at least a portion of the upper surface of the first conductive pattern 16. The second opening may be formed through a photo process to be described below. The second upper metal layer 18 and the second conductive pattern 19 to be described below may be sequentially stacked on the second opening formed in the second upper insulating layer 17.

According to an exemplary embodiment of the present inventive concept, the second upper metal layer 18 may be disposed on an inner side surface and at least a portion of an upper surface of the second upper insulating layer 17 and the upper surface of the first conductive pattern 16. The second upper metal layer 18 may come in contact with the upper surface of the first conductive pattern 16 and be electrically connected to the first conductive pattern 16. According to an exemplary embodiment of the present inventive concept, the second upper metal layer 18 may have a structure in which a plurality of metal layers are stacked. The stacked number and a material of the plurality of metal layers may be variously determined. For example, the second upper metal layer 18 may have a structure in which a Cu metal layer is stacked on a Ti metal layer.

According to an exemplary embodiment of the present inventive concept, the second conductive pattern 19 may be a re-wiring pattern filling the second opening formed in the second upper insulating layer 17. In addition, the second conductive pattern 19 may include a metal having high electrical conductivity. For example, the second conductive pattern 19 may include Cu. The second conductive pattern 19 may come in contact with the second upper metal layer 18, and accordingly, the second conductive pattern 19 may be electrically connected to the first conductive pattern 16 and the TSV 11.

According to an exemplary embodiment of the present inventive concept, the semiconductor chip 310 may be mounted on the second conductive pattern 19. A plurality of individual devices formed on the semiconductor chip 310 may be electrically connected to the TSV 11 by sequentially passing through the second conductive pattern 19, the second upper metal layer 18, the first conductive pattern 16, and the first upper metal layer 15.

According to an exemplary embodiment of the present inventive concept, the protective layer 20 may cover only a portion of the second surface 10b disposed between adjacent TSV 11 on the interposer substrate 10, and may not cover a lower surface of the TSV 11 exposed through the second surface 10b. The protective layer 20 may cover the portion of the second surface 10b of the interposer substrate 10 with a thickness of about 1 micrometer or less. The protective layer 20 may include a silicon oxide, a silicon nitride, a silicon oxynitride, and or silicon carbide. As shown in FIG. 1, a lower surface of the protective layer 20 may have substantially the same height as the lower surface of the TSV 11. For example, the lower protective layer 20 has a surface adjacent to the lower insulating layer 21 that is substantially coplanar with the lower surface of the TSV 11.

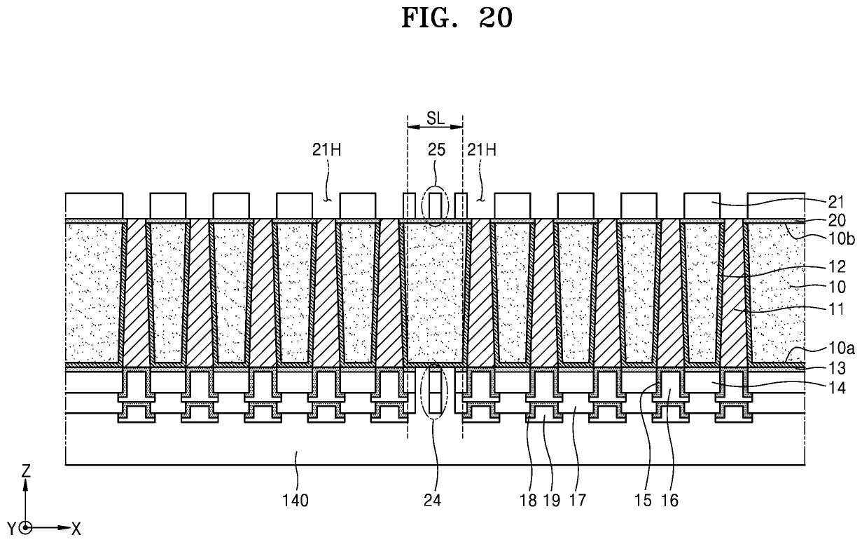

According to an exemplary embodiment of the present inventive concept, the lower insulating layer 21 may be disposed on the protective layer 20. For example, the lower insulating layer 21 may have a thickness of about 3 micrometers to about 10 micrometers on the protective layer 20 overlapping the second surface 10b of the interposer substrate 10. The lower insulating layer 21 may have a third opening (21H shown in FIG. 20), and the third opening 21H may expose the lower surface of the TSV 11 through the second surface 10b of the interposer substrate 10. The third opening 21H may be formed through the photo process to be described below. The lower metal layer 22 and the connection terminal 23 may be sequentially stacked on the third opening 21H.

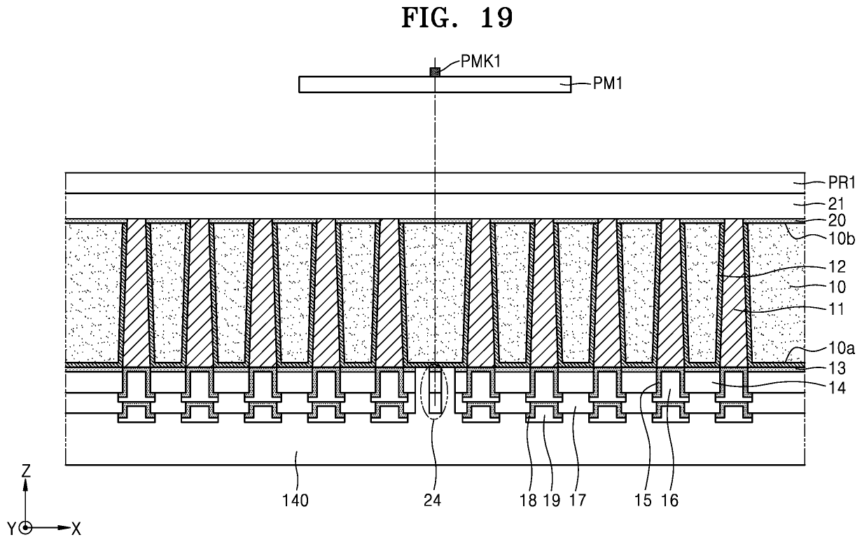

According to an exemplary embodiment of the present inventive concept, the lower insulating layer 21 may include an oxide, a nitride, and/or an oxynitride, for example, a silicon oxide, a silicon nitride, and/or a silicon oxynitride. For example, the lower insulating layer 21 may include an epoxy resin, polybenzobisoxazole (PBO), benzocyclobutene (BCB), polyimide (PI), and/or a polyimide derivative. Because the lower insulating layer 21 may include a material described above, the first alignment key 24 disposed on the first surface 10a of the interposer substrate 10 may be observed in a process of forming a lower circuit pattern including the third opening 21H by patterning the lower insulating layer 21. Accordingly, an alignment device may align an alignment key (PMK1 shown in FIG. 19) of a first photomask (PM1 shown in FIG. 19) to be described below with the first alignment key 24 on the first surface 10a of the interposer substrate 10. Accordingly, an operation of forming the lower circuit pattern by patterning the lower insulating layer 21 on the second surface 10b of the interposer substrate 10 may not include forming, on the second surface 10b, a separate alignment key for alignment with the first photomask PM1.

According to an exemplary embodiment of the present inventive concept, the lower metal layer 22 may be formed on an inner side surface and at least a portion of the lower insulating layer 21, and the lower surface of the TSV 11. In addition, the lower metal layer 22 may come in contact with the lower surface of the TSV 11 and electrically connect to the TSV 11. According to an exemplary embodiment of the present inventive concept, the lower metal layer 22 may have a structure in which a plurality of metal layers are stacked. The stacked number and a material of the plurality of metal layers may be variously changed. For example, the lower metal layer 22 may have a structure in which a Cu metal layer is stacked on a Ti metal layer.

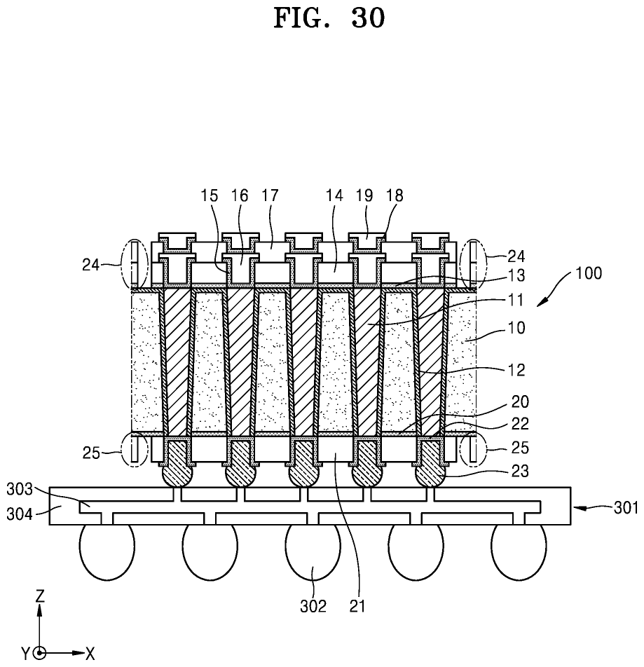

According to an exemplary embodiment of the present inventive concept, the connection terminal 23 may fill the third opening 21H formed in the lower insulating layer 21 and electrically connect the interposer 100 to a circuit board (301 of FIG. 30). The connection terminal 23 may come in contact with the lower metal layer 22 and electrically connect to the lower metal layer 22.

As shown in FIG. 1, the connection terminal 23 may include a solder ball. The connection terminal 23 may include a metal including tin, silver, Cu, and/or Al, and a shape of the connection terminal 23 may be a ball shape but is not limited thereto and may be various shapes such as cylindrical, faceted cylindrical, and polyhedral shapes.

According to an exemplary embodiment of the present inventive concept, the connection terminal 23 may be mounted on the circuit board 301. In more detail, the connection terminal 23 may be mounted on the circuit board 301 such as a system substrate or a main board and electrically connect to the circuit board 301.

According to an exemplary embodiment of the present inventive concept, the first alignment key 24 may be formed on the first surface 10a in the residual area D2 of the interposer substrate 10. The first alignment key 24 may include any one of the materials of the first upper insulating layer 14 and the second upper insulating layer 17. For example, as shown in FIG. 1, the first alignment key 24 may have a double-layer structure, wherein a first layer may include a material that is substantially the same as the material of the first upper insulating layer 14, and a second layer on the first layer may include a material that is substantially the same as the material of the second upper insulating layer 17. However, the first alignment key 24 is not limited thereto, and unlike FIG. 1, the first alignment key 24 may have a single-layer structure, wherein the single layer may include a material that is substantially the same as the material of the first upper insulating layer 14. Alternatively, the first alignment key 24 may not include the materials of the first upper insulating layer 14 and the second upper insulating layer 17 and may include a metal material such as Cu.

According to an exemplary embodiment of the present inventive concept, the second alignment key 25 may be formed on the second surface 10b in the residual area D2 of the interposer substrate 10. The second alignment key 25 may include a material that is substantially the same as the material of the lower insulating layer 21. For example, the second alignment key 25 may include at least one of an epoxy resin, PBO, BCB, PI, and a polyimide derivative. In addition, a thickness of the second alignment key 25 may be substantially the same as the thickness of the lower insulating layer 21. For example, the thickness of the second alignment key 25 may be about 3 micrometers to about 10 micrometers.

According to an exemplary embodiment of the present inventive concept, the second alignment key 25 may be formed at a position corresponding to the first alignment key 24. When viewing the interposer 100 from the top to the bottom, the second alignment key 25 may overlap the first alignment key 24. For example, the second alignment key 25 may overlap the first alignment key 24 in the third direction (e.g., a Z direction). In addition, the second alignment key 25 may have various shapes including a cylindrical shape and a rectangular parallelepiped shape.

The interposer 100 according to an exemplary embodiment of the present inventive concept may include a single patterning layer having only the first upper insulating layer 14, the first upper metal layer 15, and the first conductive pattern 16 formed on the first surface 10a by omitting the second upper insulating layer 17, the second upper metal layer 18, and the second conductive pattern 19 from the first surface 10a. However, the interposer 100 is not limited thereto and may include two or more patterning layers on the first surface 10a.

Hereinafter, a method of manufacturing the interposer 100, according to an exemplary embodiment of the present inventive concept, will be described in more detail with reference to FIGS. 2 to 28.

FIG. 2 is a top view of the interposer substrate 10 according to an exemplary embodiment of the present inventive concept. Referring to FIG. 2, the interposer substrate 10 may include the mounting area D1 and the scribe lane SL. The mounting area D1 may have components of the interposer 100 formed thereon and have the semiconductor chip mounted thereon. The scribe lane SL may include a cutting line L for individualizing the interposer substrate 10. The scribe lane SL may include the residual area D2, and the residual area D2 may be one region of the scribe lane SL, which remains after individualizing the interposer substrate 10.

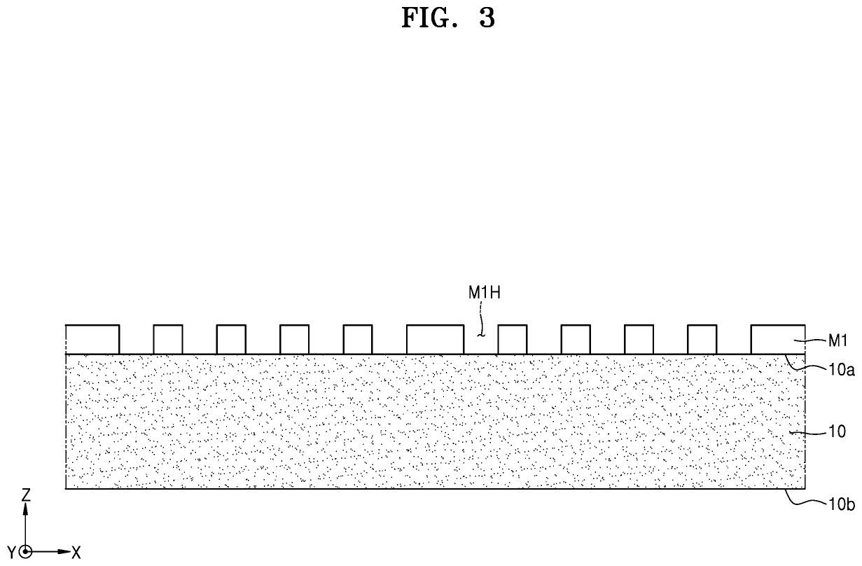

Hereinafter, FIGS. 3 to 28 show a region corresponding to a cross-section taken along line A-A of FIG. 2.

FIGS. 3 to 6 illustrate operations of forming the TSV 11 in the interposer substrate 10.

FIG. 3 illustrates an operation of forming a first mask pattern M1 on the interposer substrate 10. The interposer substrate 10 may include, for example, Si. However, the interposer substrate 10 is not limited thereto and may include a semiconductor element such as Ge and/or include a semiconductor compound such as SiC, GaAs, InAs, or InP.

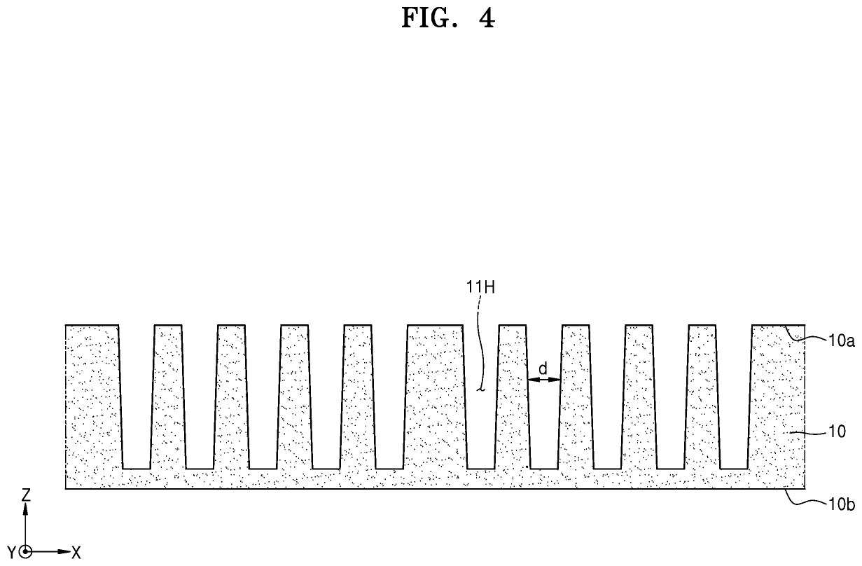

According to an exemplary embodiment of the present inventive concept, the first mask pattern M1 may have a first mask hole M1H formed to expose a portion of the first surface 10a of the interposer substrate 10 therethrough. For example, the first mask hole M1H exposing a portion of the first surface 10a may correspond to a width of an upper surface of the TSV 11 to be formed (see FIG. 4) that extends in the first direction (e.g., the X direction). The first mask pattern M1 may be formed by a photolithography process. For example, the first mask pattern M1 including the first mask hole M1H may be formed by coating a photoresist layer on the interposer substrate 10 and then patterning the photoresist layer through an exposure process and a development process.

FIG. 4 illustrates an operation of forming a through hole 11H in the interposer substrate 10. The through hole 11H may be formed by etching the interposer substrate 10 using the first mask pattern M1 as an etching mask.

According to an exemplary embodiment of the present inventive concept, the through hole 11H may be formed in the interposer substrate 10 through an anisotropy etching process, a laser drilling process, or the like. As described above, the through hole 11H may have a tapered structure in which the width d in the first direction (e.g., the X direction) decreases downward from the first surface 10a in a third direction (e.g., the Z direction) toward the second surface 10b. However, the through hole 11H is not limited thereto and may have a cylindrical or rectangular parallelepiped shape of which the width d in the first direction (e.g., the X direction) is substantially identical from the first surface 10a to the second surface 10b.

According to an exemplary embodiment of the present inventive concept, after forming the through hole 11H the first mask pattern M1 may be removed through an ashing and strip process to expose the first surface 10a of the interposer substrate 10 to the outside.

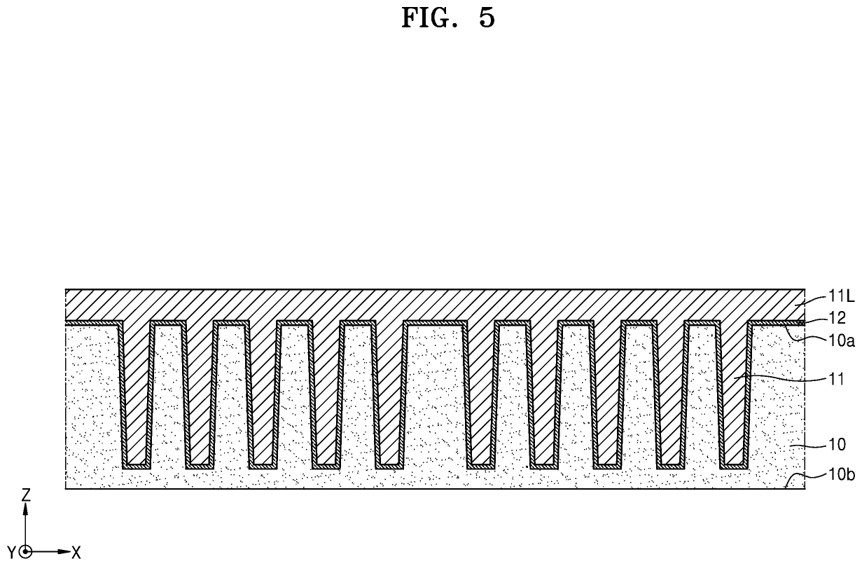

FIG. 5 illustrates an operation of forming the insulating layer 12 and a conductive material layer 11L on the interposer substrate 10. Referring to FIG. 5, the insulating layer 12 may be formed along the first surface 10a and the inner side surface of the interposer substrate 10. The insulating layer 12 may include an oxide, a nitride, and/or an oxynitride, for example, a silicon oxide, a silicon nitride, and/or a silicon oxynitride.

According to an exemplary embodiment of the present inventive concept, the conductive material layer 11L filling a space of the through hole 11H may be formed on the insulating layer 12. For example, the conductive material layer 11L may be disposed on the insulating layer 12 in both the through hole 11H and a region in which the insulating layer 12 overlaps the first surface 10a of the interposer substrate 10 in a thickness direction (e.g., the third direction Z). The conductive material layer 11L may fill the space of the through hole 11H by using an electroplating process. A conductive material, which has filled the space of the through hole 11H, may form the TSV 11. The conductive material layer 11L may include a metal material, for example, include Al, Au, Be, Bi, Co, Cu, Hf, In, Mn, Mo, Ni, Pb, Pd, Pt, Rh, Re, Ru, Ta, Te, Ti, W, Zn, and/or Zr.

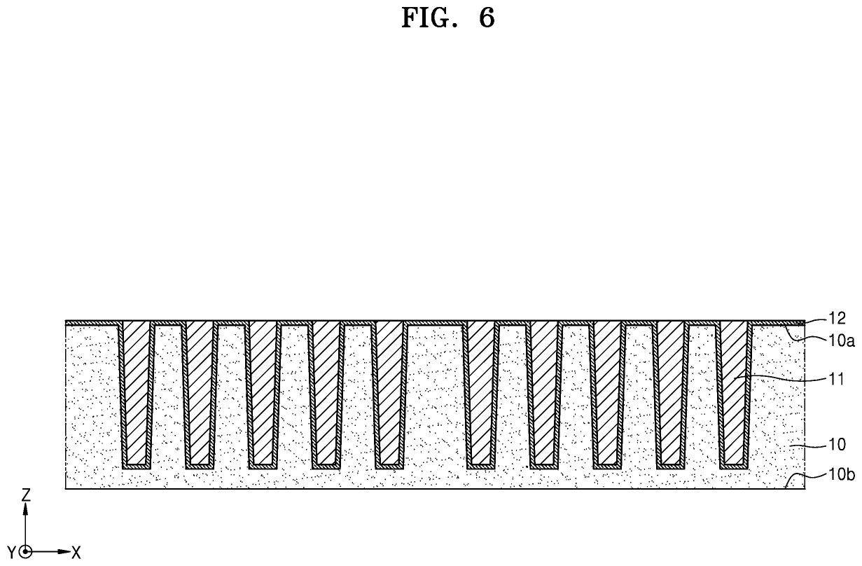

FIG. 6 illustrates an operation of etching the conductive material layer 11L to expose the insulating layer 12 to the outside. Referring to FIG. 6, the conductive material layer 11L may be etched through a chemical mechanical polishing (CMP) process or an etch-back process by using the insulating layer 12 as a stopper. By the etching, one surface of the insulating layer 12 and the upper surface of the TSV 11 may be exposed to the outside. In addition, the one surface of the insulating layer 12 may be located at the same height as the upper surface of the TSV 11. For example, the one surface of the insulating layer 12 may be coplanar with the upper surface of the TSV 11.

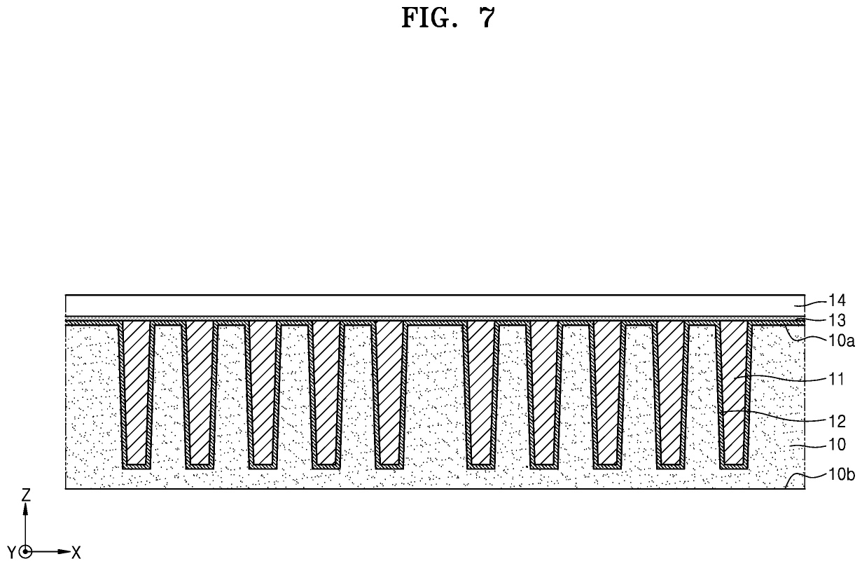

FIGS. 7 to 13 illustrate operations of forming components of the interposer 100 on the first surface 10a of the interposer substrate 10.

FIG. 7 illustrates an operation of forming the etch stopping layer 13 and the first upper insulating layer 14 on the first surface 10a of the interposer substrate 10. Referring to FIG. 7, the etch stopping layer 13 may be formed on an upper surface of the insulating layer 12 and the upper surface of the TSV 11. For example, the etch stopping layer 13 may overlap both the upper surface of the insulating layer 12 and the upper surface of the TSV 11 in a thickness direction (e.g., the third direction Z). After forming the etch stopping layer 13, the first upper insulating layer 14 may be formed on the etch stopping layer 13. For example, the first upper insulating layer 14 may overlap the etch stopping layer 13 in a thickness direction (e.g., the third direction Z). The first upper insulating layer 14 may include a silicon oxide, a silicon nitride, a silicon oxynitride, a silicon carbide, or the like. According to an exemplary embodiment of the present inventive concept, a material of the etch stopping layer 13 may differ from a material of the first upper insulating layer 14, and a thickness of the etch stopping layer 13 may be less than a thickness of the first upper insulating layer 14. However, the etch stopping layer 13 and the first upper insulating layer 14 are not limited thereto.

FIG. 8 illustrates an operation of forming a first upper circuit pattern and the first alignment key 24 by patterning the first upper insulating layer 14. Referring to FIG. 8, the first upper circuit pattern may include the first opening 14H formed in the first upper insulating layer 14. For example, the first opening 14H may have a width that corresponds to and exposes the upper surface of the TSV 11. The first upper metal layer 15 and the first conductive pattern 16 may be sequentially stacked on the first opening 14H. For example, the first upper metal layer 15 and the first conductive pattern 16 may be sequentially stacked in a thickness direction (e.g., the Z direction).

According to an exemplary embodiment of the present inventive concept, an operation of forming the first upper metal layer 15 may include forming the first opening 14H in the first upper insulating layer 14 by patterning the first upper insulating layer 14 by a photolithography process. After coating the first upper insulating layer 14 on the etch stopping layer 13, the first upper insulating layer 14 may be patterned through an exposure process and a development process to form the first opening 14H in the first upper insulating layer 14. Referring to FIG. 8, the first opening 14H may expose the upper surface of the TSV 11 to the outside through the first surface 10a of the interposer substrate 10.

According to an exemplary embodiment of the present inventive concept, an operation of forming the first alignment key 24 may include patterning the first upper insulating layer 14 through a photolithography process to form the first alignment key 24 on the scribe lane SL. Accordingly, the first alignment key 24 may include the material of the first upper insulating layer 14. However, the first alignment key 24 is not limited thereto and may be formed on the scribe lane SL through a separate process and/or a separate material. For example, the first alignment key 24 might not be formed by patterning the first upper insulating layer 14 and may be formed on the scribe lane SL through the separate process. According to an exemplary embodiment of the present inventive concept, the first alignment key 24 formed on the first surface 10a of the interposer substrate 10 may be aligned with the alignment key PMK1 of the first photomask PM1 in the operation of forming the lower circuit pattern by patterning the lower insulating layer 21 on the second surface 10b. Accordingly, a separate alignment key for patterning the lower insulating layer 21 on the second surface 10b of the interposer substrate 10 may not have to be formed.

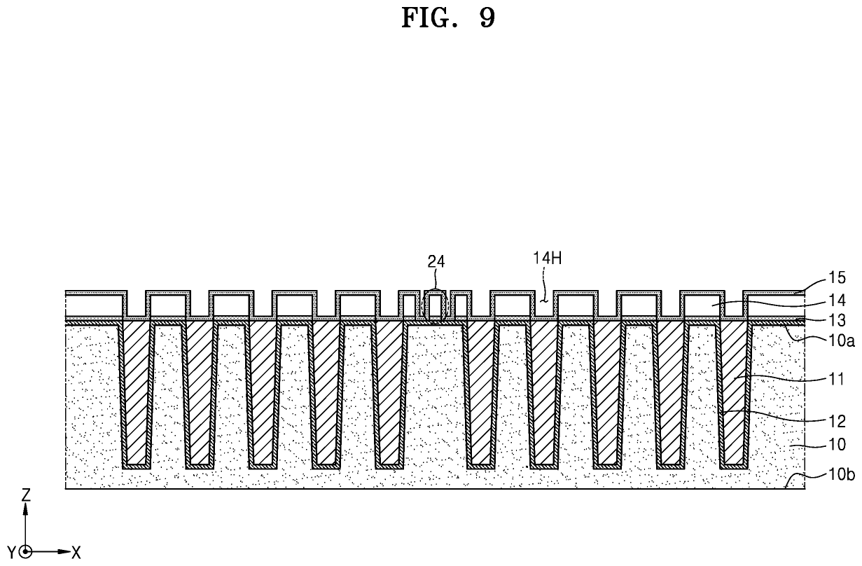

FIG. 9 illustrates an operation of forming the first upper metal layer 15 on the first upper insulating layer 14. The first upper metal layer 15 may be formed on the upper surface and the inner side surface of the first upper insulating layer 14 and the upper surface of the TSV 11. The first upper metal layer 15 may cover the upper surface of the TSV 11 and come in contact with the TSV 11.

According to an exemplary embodiment of the present inventive concept, the operation of forming the first upper metal layer 15 may include forming the first upper metal layer 15 by stacking a plurality of metal layers. The stacked number and a material of the plurality of metal layers may be variously changed. For example, the operation of forming the first upper metal layer 15 may include stacking a Cu metal layer on a Ti metal layer.

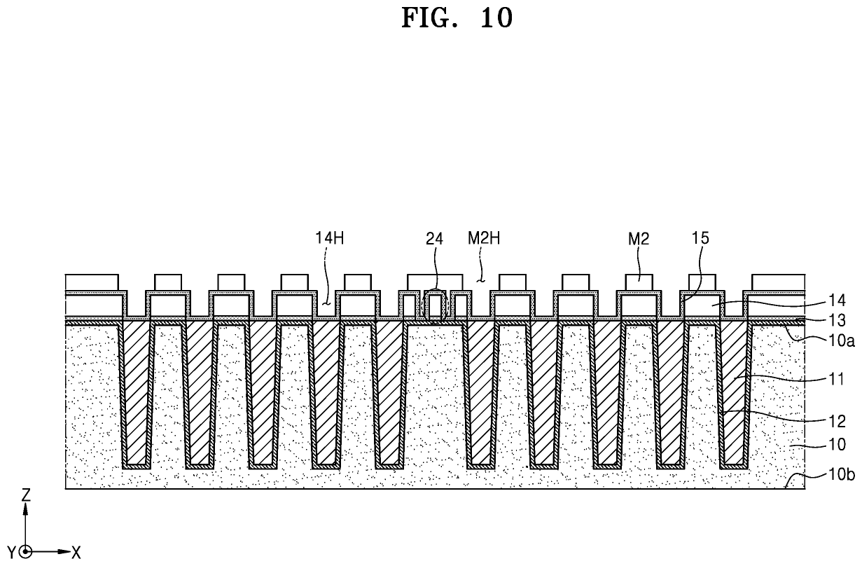

FIG. 10 is a cross-sectional view showing an operation of forming a second mask pattern M2 on the first upper metal layer 15. According to an exemplary embodiment of the present inventive concept, the second mask pattern M2 may have a second mask hole M2H formed to expose the first opening 14H described above. The second mask pattern M2 may be formed through a photolithography process. For example, the second mask pattern M2 including the second mask hole M2H may be formed by coating a photoresist layer on the first upper metal layer 15 and then patterning the photoresist layer through an exposure process and a development process. Portions of the second mask pattern M2 may be narrower in the first direction (e.g., the X direction) than corresponding portions of the first upper insulating layer 14 and first upper metal layer 15 overlapped in the third direction (e.g., the Z direction).

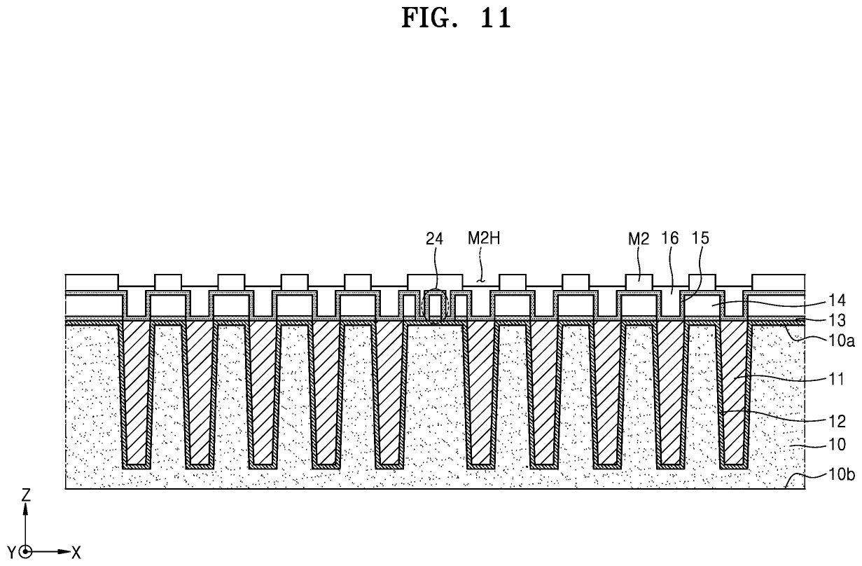

FIG. 11 illustrates an operation of forming the first conductive pattern 16 on the first opening 14H and the second mask hole M2H. For example, the operation of forming the first conductive pattern 16 on the first opening 14H and the second mask hole M2H may include forming the first conductive pattern 16 by filling the first opening 14H and the second mask hole M2H with a conductive material. The conductive material may fill the first opening 14H and the second mask hole M2H by using an electroplating process, and an upper surface of the conductive material may be lower than an upper surface of the second mask pattern M2. The conductive material, which has filled the first opening 14H and the second mask hole M2H between adjacent portions of the second mask pattern M2, may form the first conductive pattern 16.

According to an exemplary embodiment of the present inventive concept, the first conductive pattern 16 may include a metal having high electrical conductivity, and for example, the first conductive pattern 16 may include Cu. The first conductive pattern 16 may come in contact with the first upper metal layer 15 and may be electrically connected to the TSV 11.

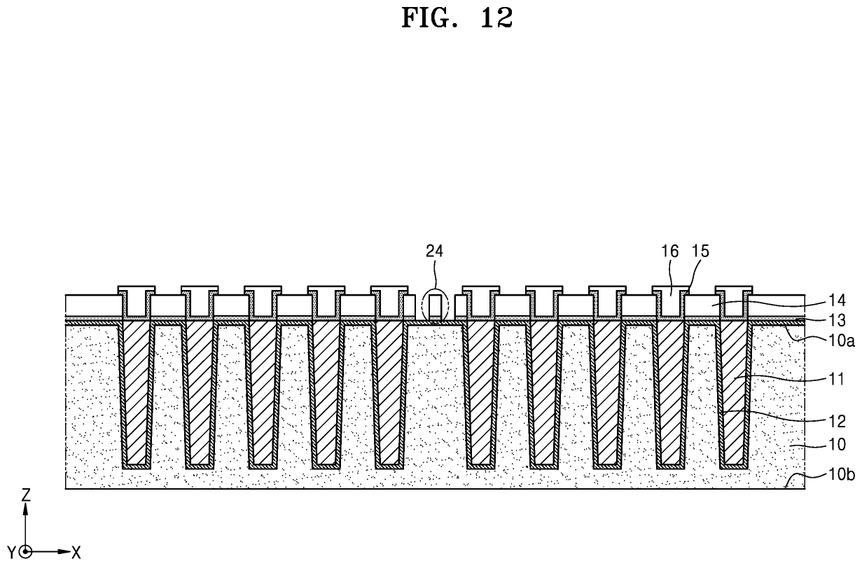

FIG. 12 illustrates an operation of removing the second mask pattern M2 and etching at least a portion of the first upper metal layer 15 disposed thereunder. Referring to FIG. 12, an operation of removing the second mask pattern M2 may include removing the second mask pattern M2 through an ashing and strip process. In addition, an operation of etching at least a portion of the first upper metal layer 15 may include selectively etching only a portion of the first upper metal layer 15 located at a lower part of the second mask pattern M2. For example, a portion of the first upper metal layer 15 etched below the removed second mask pattern M2 may have a width in the first direction (e.g., the X direction) that corresponds to a width of a removed portion of the second mask pattern M2. Accordingly, the first upper metal layer 15 may remain disposed on both the first opening 14H and at least partially on the upper surface of the first insulating layer 14 on adjacent sides of the first opening 14H. Thus, the first upper metal layer 15 located at a lower part of the first conductive pattern 16 may remain without being etched.

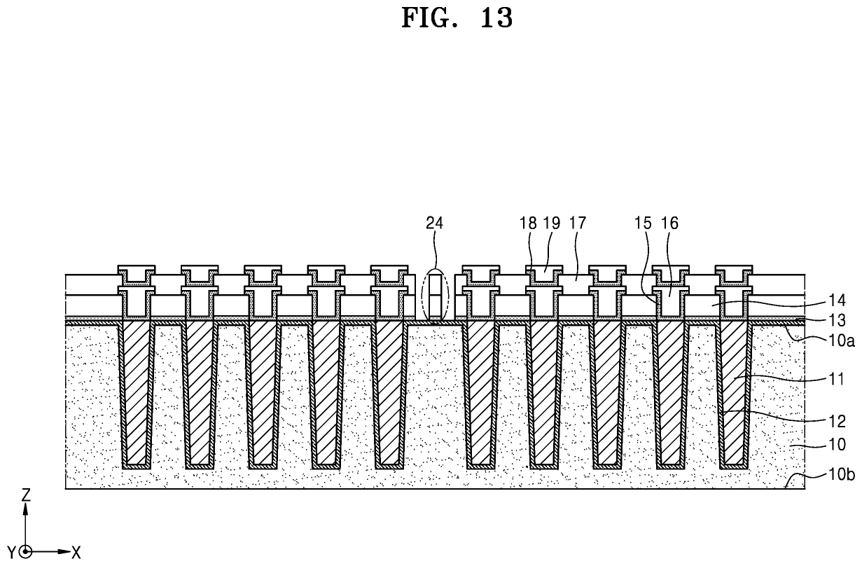

FIG. 13 illustrates operations of forming the second upper insulating layer 17, the second upper metal layer 18, and the second conductive pattern 19. The operations of firming the second upper insulating layer 17, the second upper metal layer 18, and the second conductive pattern 19 may be substantially the same as the technical idea of the operations of forming the first upper insulating layer 14, the first upper metal layer 15, and the first conductive pattern 16, which have been described with reference to FIGS. 7 to 12, and thus, a detailed description thereof is omitted.

According to an exemplary embodiment of the present inventive concept, a second upper circuit pattern may be formed on the second upper insulating layer 17, and the second upper circuit pattern may include a second opening (not shown) formed in the second upper insulating layer 17. The second upper metal layer 18 and the second conductive pattern 19 may be sequentially stacked on the second opening.

According to an exemplary embodiment of the present inventive concept, the operations of forming components on the first surface 10a of the interposer substrate 10 may omit the operations of forming the second upper insulating layer 17, the second upper metal layer 18, and the second conductive pattern 19. Accordingly, the interposer 100 may include a single patterning layer having only the first upper insulating layer 14, the first upper metal layer 15, and the first conductive pattern 16. However, the operations of forming components on the first surface 10a of the interposer substrate 10 are not limited thereto and may include forming two or more patterning layers including an upper insulating layer, an upper metal layer, and a conductive pattern.

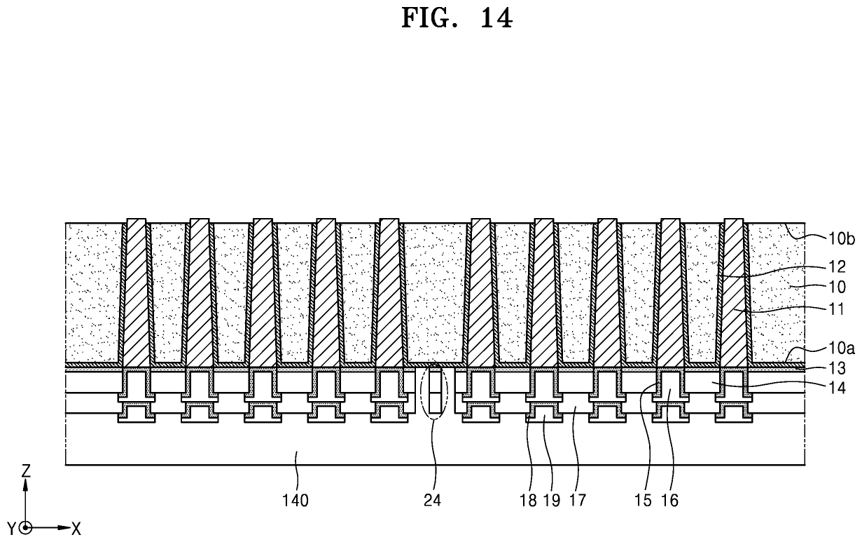

Operations of the method of manufacturing the interposer 100, which are to be described with reference to FIGS. 14 to 28, may be performed after turning the interposer substrate 10 upside down by 180 degrees. The operations of the method of manufacturing the interposer 100 may be performed in a state in which a protective carrier 140 is attached onto the first surface 10a, to protect the components formed on the first surface 10a by the methods of manufacturing the interposer 100, which have been described above.

FIGS. 14 to 16 illustrate operations of exposing the TSV 11 through the second surface 10b of the interposer substrate 10 and then etching a portion of the TSV 11.

FIG. 14 illustrates an operation of exposing the TSV 11 through the second surface 10b of the interposer substrate 10. Referring to FIG. 14, the operation of exposing the TSV 11 through the second surface 10b of the interposer substrate 10 may include etching the interposer substrate 10 from the second surface 10b toward the first surface 10a. Accordingly, the lower surface and at least a portion of a side surface of the TSV 11 may be exposed through the second surface 10b of the interposer substrate 10. The interposer substrate 10 may be etched by various etching processes including mechanical etching, chemical etching, and the like. The etch selectivity of the interposer substrate 10 may be greater than an etch selectivity of the material used in the TSV 11 and the material of the insulating layer 12. Thus, the lower surface of the TSV 11 may protrude further in the third direction (e.g., the Z direction) than a plane of the second surface 10b of the interposer substrate 10.

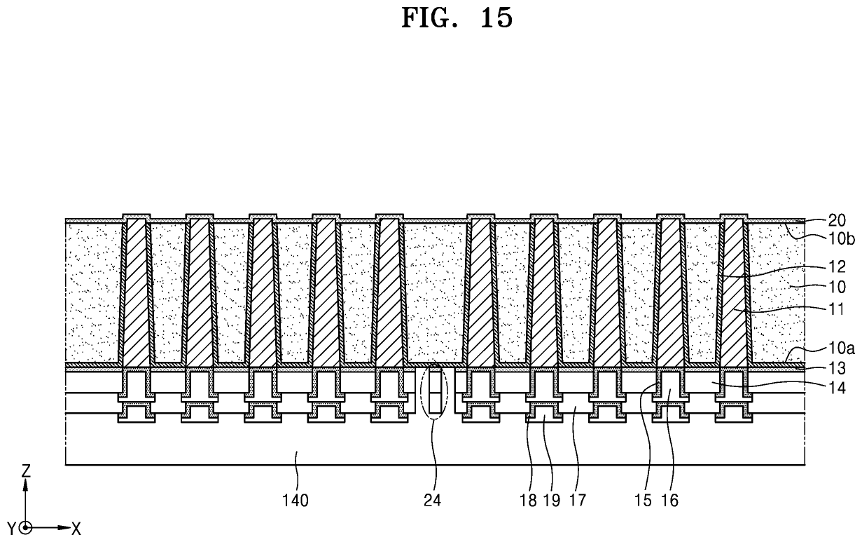

FIG. 15 illustrates an operation of forming the protective layer 20 on the second surface 10b of the interposer substrate 10 and the lower surface of the TSV 11. The operation of firming the protective layer 20 may include covering the second surface 10b of the interposer substrate 10 and the exposed lower surface and side surface of the TSV 11 with the protective layer 20 having a thickness of about 1 micrometer or less. The protective layer 20 may include a silicon oxide, a silicon nitride, a silicon oxynitride and/or a silicon carbide.

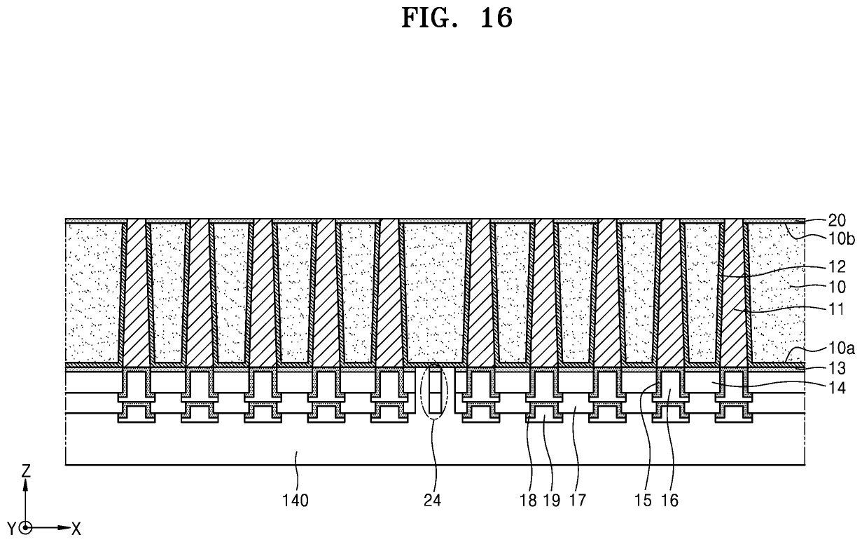

FIG. 16 illustrates an operation of etching a portion of the protective layer 20 and the TSV 11. The operation of etching the portion of the protective layer 20 and the TSV 11 may include etching the portion of the protective layer 20 and the TSV 11 from the second surface 10b toward the first surface 10a to expose the TSV 11 through the second surface 10b. For example, a lower surface of the TSV 11 and the protective layer 20 may be planarized.

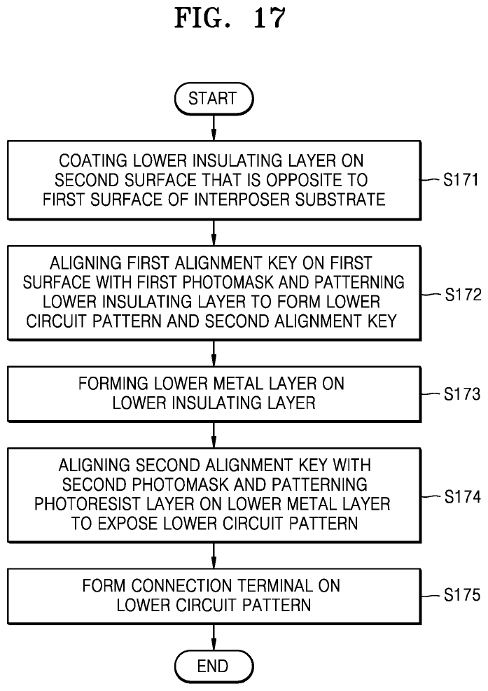

FIG. 17 is a flowchart of operations of forming components of the interposer 100 on the second surface 10b of the interposer substrate 10. The operation of forming components of the interposer 100 on the second surface 10b of the interposer substrate 10 may include: coating the lower insulating layer 21 on the second surface 10b that is opposite to the first surface 10a of the interposer substrate 10 (operation S171); aligning the first alignment key 24 on the first surface 10a with the first photomask PM1 and patterning the lower insulating layer 21 to form the lower circuit pattern and the second alignment key 25 (operation S172); forming the lower metal layer 22 on the lower insulating layer 21 (operation S173); aligning the second alignment key 25 with a second photomask PM2 and patterning a photoresist layer on the lower metal layer 22 to expose the lower circuit pattern (operation S174); and forming the connection terminal 23 on the lower circuit pattern (operation S175).

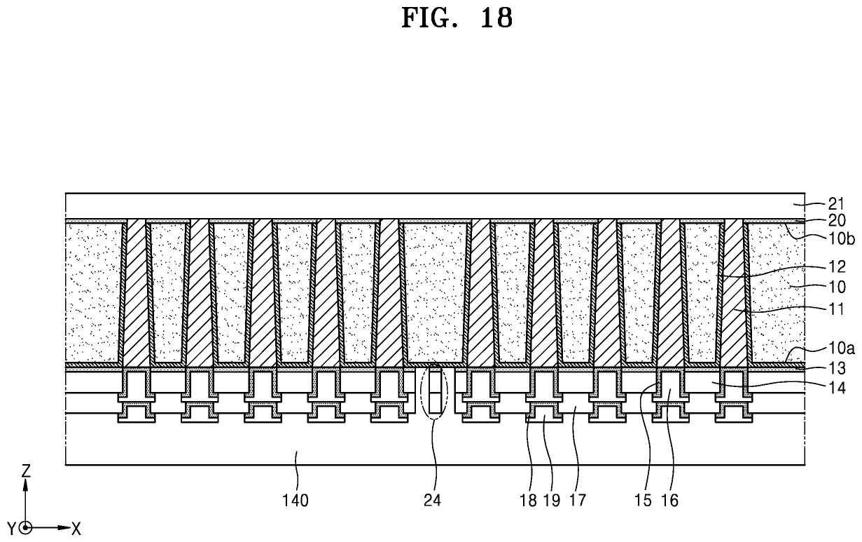

FIGS. 18 to 27 illustrate operations of forming components of the interposer 100 on the second surface 10b of the interposer substrate 10.

FIG. 18 illustrates operation S171 of coating the lower insulating layer 21 on the second surface 10b of the interposer substrate 10. Operation S171 of coating the lower insulating layer 21 may include coating the lower insulating layer 21 with a thickness of about 3 micrometers to about 10 micrometers on the second surface 10b of the interposer substrate 10.

According to an exemplary embodiment of the present inventive concept, operation S171 of coating the lower insulating layer 21 may include coating at least one of an epoxy resin, PBO, BCB, PI, and a polyimide derivative on the second surface 10b of the interposer substrate 10. Because the lower insulating layer 21 may include the material described above, the first alignment key 24 on the first surface 10a of the interposer substrate 10 may be observed by the alignment device in an operation of forming the lower circuit pattern including the third opening 21H on the lower insulating layer 21. The alignment device may align the alignment key PMK1 of the first photomask PM1, to be described below, with the first alignment key 24 on the first surface 10a of the interposer substrate 10. Accordingly, the operation of forming the lower circuit pattern by patterning the lower insulating layer 21 on the second surface 10b of the interposer substrate 10 might not include forming, on the second surface 10b, a separate alignment key for alignment with the first photomask PM1. Therefore, a process of manufacturing the interposer 100 may be simplified, and manufacturing costs may be reduced.

FIG. 19 illustrates an operation of aligning the first alignment key 24 on the first surface 10a of the interposer substrate 10 with the first photomask PM1, and FIG. 20 illustrates an operation of forming the lower circuit pattern and the second alignment key 25 by patterning the lower insulating layer 21 by the first photomask PM1.

Referring to FIG. 19, a first photoresist layer PR1 may be coated on the lower insulating layer 21. In addition, the alignment key PMK1 of the first photomask PM1 located on an upper side of the second surface 10b of the interposer substrate 10 may be aligned with the first alignment key 24 on the first surface 10a of the interposer substrate 10. For example, the lower insulating layer 21 may include an epoxy resin, PBO, BCB, PI, and/or a polyimide derivative described above, and a layer including a metal material might not be formed between the first photomask PM1 and the first alignment key 24. Accordingly, the alignment device may observe the first alignment key 24 on the first surface 10a from an upper side of the second surface 10b and align the alignment key PMK1 of the first photomask PM1 with the first alignment key 24. According to an exemplary embodiment of the present inventive concept, the first alignment key 24 may have a width in the first direction (e.g., the X direction) that is substantially the same as a width of the alignment key PMK1 in the first direction (e.g., the X direction).

Referring to FIG. 20, the lower circuit pattern and the second alignment key 25 may be formed on the lower insulating layer 21 by patterning the first photoresist layer PR1 using the first photomask PM1. The lower circuit pattern may include the third opening 21H. According to an exemplary embodiment of the present inventive concept, the operation of forming the lower circuit pattern and the second alignment key 25 by patterning the lower insulating layer 21 by the fnst photomask PM1 may include simultaneously forming the lower circuit pattern and the second alignment key 25. The lower circuit pattern and the second alignment key 25 may be simultaneously formed by patterning the lower insulating layer 21 through a pattern formed on the first photomask PM1. According to an exemplary embodiment of the present inventive concept, the first photomask PM1 may be applied to a positive or negative photoresist layer PR1 to expose portions of the lower insulating layer 21 that will correspond to subsequently etched third openings 21H and the second alignment key 25. In such a case, the remnants of the photoresist layer PR1 remaining after the photoresist patterning and etching operations may be removed by another process.

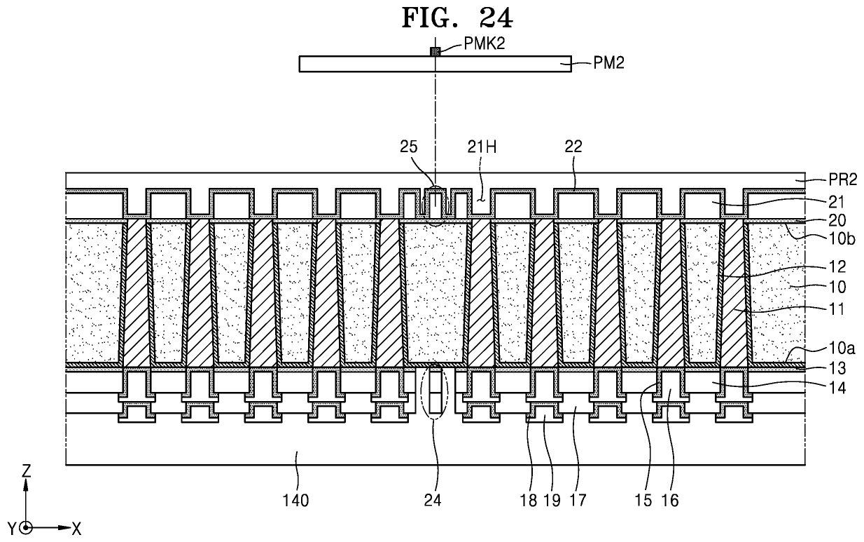

Accordingly, the thickness of the lower insulating layer 21 may be substantially the same as the thickness (e.g., a height in the third direction Z) of the second alignment key 25. The second alignment key 25 may be aligned with an alignment key PMK2 of the second photomask PM2 in an operation of patterning a second photoresist layer PR2 on the metal layer 22, which is to be described below (see FIG. 24).

According to an exemplary embodiment of the present inventive concept, the operation of forming the second alignment key 25 may include forming the second alignment key 25 on the scribe lane SL of the second surface 10b. With respect to the scribe lane SL of the interposer substrate 10, the second alignment key 25 may be observed on a side surface of a diced interposer 100.

According to an exemplary embodiment of the present inventive concept, the operation of forming the second alignment key 25 may include forming the second alignment key 25 on the second surface 10b at a position corresponding to the first alignment key 24. As shown in FIG. 20, the second alignment key 25 may be formed at a position corresponding to the first alignment key 24. In other words, when viewing the interposer substrate 10 from the top to the bottom, the second alignment key 25 may spatially overlap the first alignment key 24. For example, the second alignment key 25 may overlap the first alignment key 24 in a third direction (e.g., the Z direction).

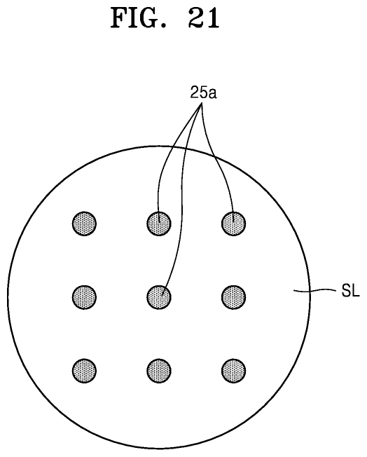

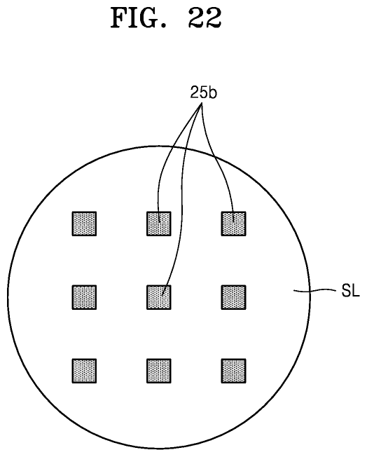

FIGS. 21 and 22 are top views showing shapes of the second alignment key 25. According to an exemplary embodiment of the present inventive concept, the operation of forming the second alignment key 25 may include forming the second alignment key 25 on the second surface 10b in a shape of a cylindrical-shaped alignment key 25a or a rectangular parallelepiped-shaped alignment key 25b. However, the shape of the second alignment key 25 is not limited to the shapes described above and may include various shapes such as an oval shape and a polyhedral shape.

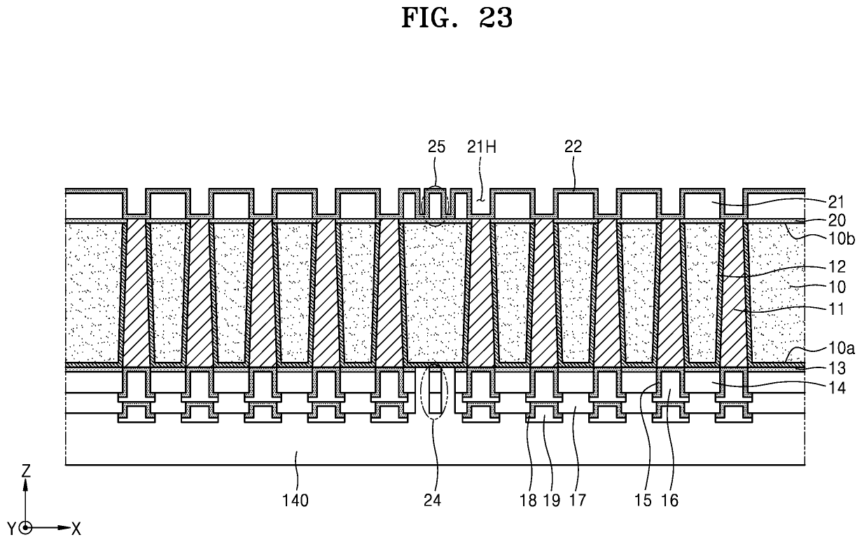

FIG. 23 illustrates operation S173 of forming the lower metal layer 22 on the lower insulating layer 21. The lower metal layer 22 may be formed on one surface and an inner side surface of the lower insulating layer 21 and the lower surface of the TSV 11. The lower metal layer 22 may cover the lower surface of the TSV 11 and come in contact with the TSV 11.

According to an exemplary embodiment of the present inventive concept, operation S173 of forming the lower metal layer 22 may include forming the lower metal layer 22 by stacking a plurality of metal layers. The stacked number and a material of the plurality of metal layers may be variously determined. For example, the operation of forming the lower metal layer 22 may include stacking a Cu metal layer on a Ti metal layer.

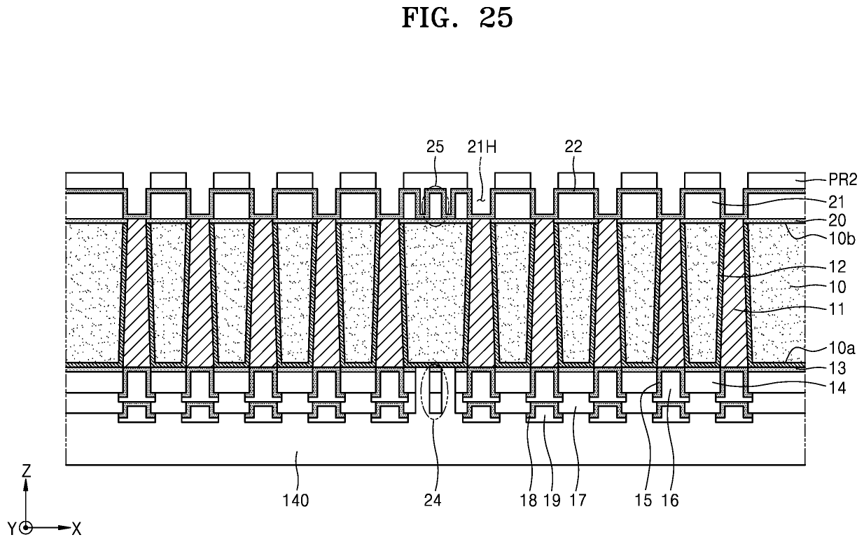

FIG. 24 illustrates an operation of aligning the second alignment key 25 with the second photomask PM2, and FIG. 25 illustrates operation S174 of exposing the lower circuit pattern by patterning the second photoresist layer PR2 on the lower metal layer 22.

Referring to FIG. 24, the second photoresist layer PR2 may be coated on the lower metal layer 22. In addition, the alignment key PMK2 of the second photomask PM2 may be aligned with the second alignment key 25 on the second surface 10b of the interposer substrate 10. The lower metal layer 22 may be interposed between the second photomask PM2 and the first alignment key 24, and the alignment device cannot observe the first alignment key 24 on the first surface 10a due to the lower metal layer 22. However, the alignment device may observe the second alignment key 25 on the second surface 10b and align the alignment key PMK2 of the second photomask PM2 with the second alignment key 25.

Referring to FIG. 25, the lower circuit pattern may be exposed by patterning the second photoresist layer PR2 using the second photomask PM2. The third opening 21H formed in the lower insulating layer 21 may be exposed by patterning the second photoresist layer PR2 using the second photomask PM2. In addition, a space formed by patterning the second photoresist layer PR2 may provide a space in which at least a portion of the connection terminal 23 is located.

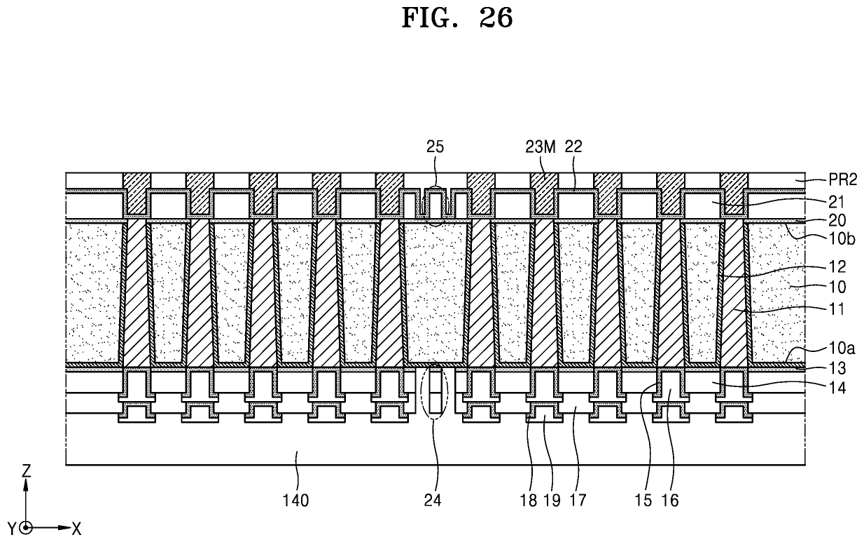

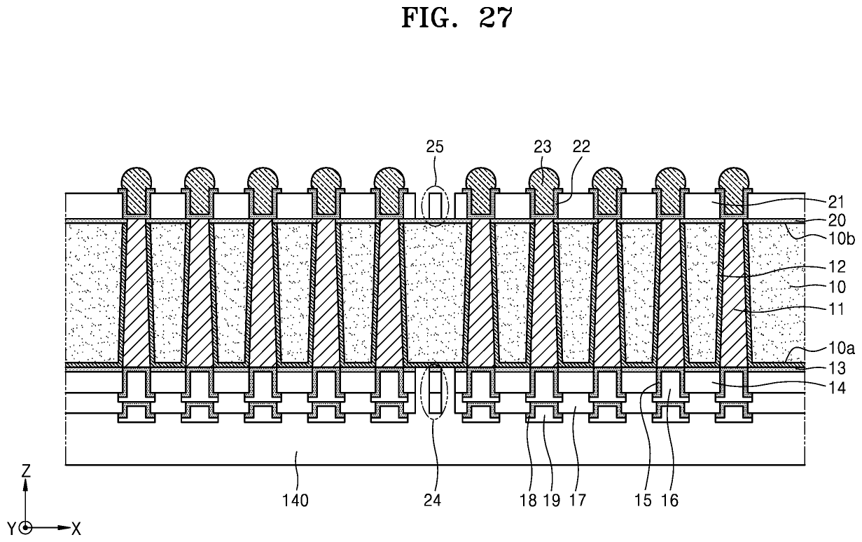

FIGS. 26 and 27 illustrate operation S175 of forming the connection terminal 23 on the lower circuit pattern.

Referring to FIG. 26, the operation of forming the connection terminal 23 may include filling a metal 23M in the third opening 21H fanned in the lower insulating layer 21 and the space formed in the second photoresist layer PR2. The metal 23M may include tin, silver, Cu, and/or Al.

Referring to FIG. 27, the operation of forming the connection terminal 23 may include: removing the second photoresist layer PR2 and re-flowing the connection terminal 23. The second photoresist layer PR2 may be removed by an ashing and strip process. After removing the second photoresist layer PR2, the connection terminal 23 may be formed on the lower circuit pattern in various shapes such as a ball shape, a cylindrical shape, a faceted cylindrical shape, or a polyhedral shape through a re-flow process.

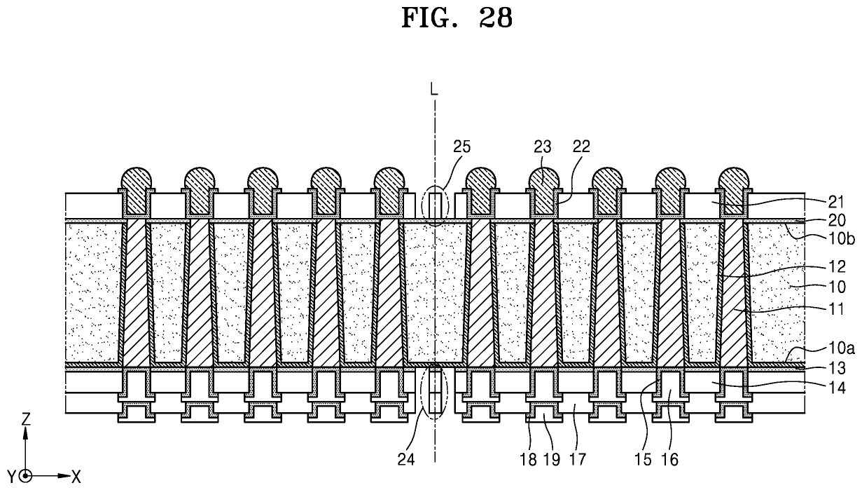

FIG. 28 illustrates an operation of cutting the interposer substrate 10. The method of manufacturing the interposer 100 may further include the operation of cutting the interposer substrate 10. According to an exemplary embodiment of the present inventive concept, the operation of cutting the interposer substrate 10 may include delaminating the protective carrier 140 from the interposer substrate 10.

According to an exemplary embodiment of the present inventive concept, the operation of cutting the interposer substrate 10 may include cutting the interposer substrate 10 along the scribe lane SL having the second alignment key 25. When the interposer substrate 10 is cut to separate interposers 100 according to an exemplary embodiment of the present inventive concept, the second alignment key 25 may be observed on a side surface of the interposer 100.

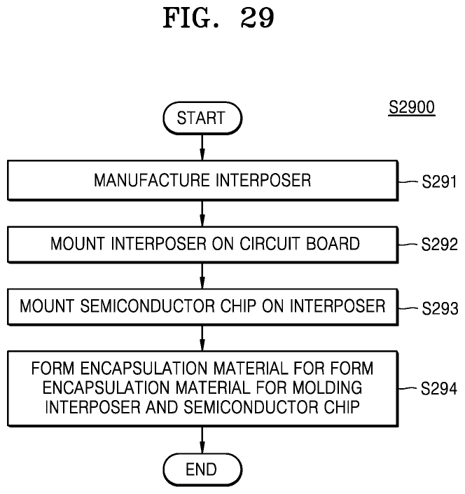

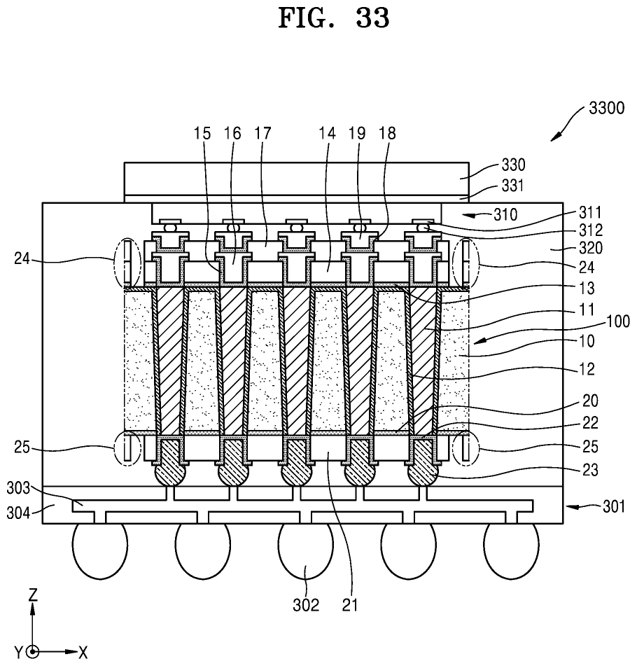

A method S2900 of manufacturing a semiconductor package (3100 of FIG. 33) including the interposer 100 according to the inventive concept will be described with reference to FIGS. 29 to 33.

FIG. 29 is a flowchart of the method S2900 of manufacturing the semiconductor package 3300 including the interposer 100. The method S2900 of manufacturing the semiconductor package 3300 may include operation S291 of manufacturing the interposer 100, operation S292 of mounting the interposer 100 on the circuit board 301, operation S293 of mounting the semiconductor chip 310 on the interposer 100, and operation S294 of forming an encapsulation material for molding the interposer 100 and the semiconductor chip 310.

The operation S291 of manufacturing the interposer 100 is substantially the same as described above with reference to FIGS. 2 to 28, and thus a detailed description thereof is omitted herein.

FIGS. 30 to 33 illustrate operations of the method S2900 of manufacturing the semiconductor package 3300 including the interposer 100 according to an exemplary embodiment of the present inventive concept.

FIG. 30 illustrates operation S292 of mounting the interposer 100 on the circuit board 301. The circuit board 301 may include a system substrate, a main board, and the like. Referring to FIG. 30, the circuit board 301 may include an external connection terminal 302, a rewiring pattern 303, and an insulating pattern 304. The interposer 100 may be mounted on the circuit board 301 and electrically connected to the circuit board 301. In more detail, the connection terminal 23 of the interposer 100 may be flip-chip-bonded on the circuit board 301, connected to the rewiring pattern 303, and electrically connected to the external connection terminal 302.

According to an exemplary embodiment of the present inventive concept, operation S292 of mounting the interposer 100 on the circuit board 301 may include aligning the interposer 100 with the circuit board 301 by using the first alignment key 24 and/or the second alignment key 25 of the interposer 100. In more detail, after cutting the interposer substrate 10, the interposer 100 may be aligned with the circuit board 301 by using the first alignment key 24 and/or the second alignment key 25 remaining in the residual area D2, thereby easily mounting the interposer 100 on the circuit board 301.

FIG. 31 illustrates operation S293 of mounting the semiconductor chip 310 on the interposer 100. According to an exemplary embodiment of the present inventive concept, the semiconductor chip 310 may be a volatile memory semiconductor device such as dynamic random access memory (DRAM) or static random access memory (SRAM) or a non-volatile memory semiconductor deice such as phase-change random access memory (PRAM), magneto-resistive random access memory (MRAM), ferroelectric random access memory (FeRAM), or resistive random access memory (RRAM). Alternatively, the semiconductor chip 310 may be a logic semiconductor device such as a central processing unit (CPU), a graphics processing unit (GPU), or an application processor (AP).

According to an exemplary embodiment of the present inventive concept, operation S293 of mounting the semiconductor chip 310 on the interposer 100 may include electrically connecting a terminal 312 formed at a lower part of a chip pad 311 of the semiconductor chip 310 to the second conductive pattern 19. For example, the terminal 312 may be connected to the second conductive pattern 19 by flip chip bonding. Accordingly, a plurality of individual devices formed on the semiconductor chip 310 may be electrically connected to the circuit board 301 through the interposer 100.

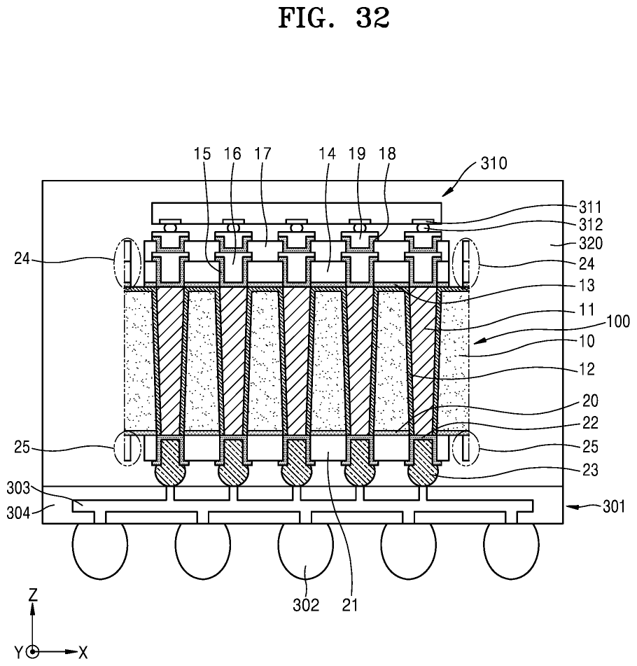

FIG. 32 illustrates operation S294 of forming an encapsulation material 320 for molding the interposer 100 and the semiconductor chip 310.

Referring to FIG. 32, the operation of forming the encapsulation material 320 may include encompassing side surfaces and upper surfaces of the interposer 100 and the semiconductor chip 310 by using the encapsulation material 320. The encapsulation material 320 may include a silicon-based material, a thermosetting material, and/or a thermoplastic material. For example, the encapsulation material 320 may include an epoxy molding compound.

FIG. 33 illustrates an operation of cutting the encapsulation material 320 and mounting a heat sink 330 thereon. The method S2900 of manufacturing the semiconductor package 3300 may further include the operation of cutting the encapsulation material 320 and mounting a heat sink 330 thereon. According to an exemplary embodiment of the present inventive concept, the operation of cutting the encapsulation material 320 may include cutting the encapsulation material 320 to expose an upper surface and side surfaces of the semiconductor chip 310. In addition, the operation of mounting the heat sink 330 may include coating an adhesive film 331 on the upper surface of the semiconductor chip 310 and then mounting the heat sink 330 on the adhesive film 331.

While the inventive concept has been particularly shown and described with reference to exemplary embodiments thereof, it will be understood that various changes in form and details may be made therein without departing from the spirit and scope of the present inventive concept, the scope of which is defined by the appended claims.

What is claimed is:

1. A method of manufacturing an interposer, the method comprising:
disposing a lower insulating layer on a second surface opposite to a first surface of an interposer substrate;
aligning a first alignment key on the first surface with a first photomask;
patterning the lower insulating layer with the first photomask to form a lower circuit pattern and a second alignment key on the second surface;
forming a lower metal layer on the lower insulating layer;
aligning the second alignment key with a second photomask; and
patterning a photoresist layer on the lower metal layer to expose the lower circuit pattern using the second photomask.

2. The method of claim 1, wherein the forming of the lower circuit pattern and the second alignment key comprises simultaneously forming the lower circuit pattern and the second alignment key by patterning the lower insulating layer.

3. The method of claim 1, wherein the forming of the second alignment key comprises forming the second alignment key on a scribe lane of the second surface.

4. The method of claim 1, wherein the forming of the second alignment key comprises:
forming the second alignment key in a cylindrical shape or a rectangular parallelepiped shape.

5. The method of claim 1, wherein the forming of the second alignment key comprises forming the second alignment key at a position overlapping the first alignment key in a thickness direction of the interposer substrate.

6. The method of claim 1, wherein the coating of the lower insulating layer comprises coating the second surface with an epoxy resin, polybenzobisoxazole (PBO), benzocyclobutene (BCB), polyimide, (PI) and/or a polyimide derivative.

7. The method of claim 1, wherein the coating of the lower insulating layer comprises coating the lower insulating layer on the second surface with a thickness of about 3 micrometers to about 10 micrometers.

8. The method of claim 1, further comprising cutting the interposer substrate,
wherein the cutting of the interposer substrate comprises cutting the interposer substrate at the second alignment key.

9. A method of manufacturing an interposer, the method comprising:
forming a through silicon via (TSV) in an interposer substrate;
disposing an upper insulating layer on a first surface of the interposer substrate;
forming an upper circuit pattern and a first alignment key by patterning the upper insulating layer;
disposing an upper metal layer on the upper insulating layer;
forming a conductive pattern on the upper metal layer;
disposing a lower insulating layer on the second surface;
aligning the first alignment key with a first photomask and patterning the lower insulating layer with the first photomask to form a lower circuit pattern and a second alignment key on the second surface;
forming a lower metal layer on the lower insulating layer;
aligning the second alignment key and a second photomask and patterning a photoresist layer on the lower metal layer to expose the lower circuit pattern; and
forming a connection terminal on the lower circuit pattern.

10. The method of claim 9, wherein the forming of the lower circuit pattern and the second alignment key comprises patterning the lower insulating layer to simultaneously form the lower circuit pattern and the second alignment key,
wherein a thickness of the lower insulating layer is the same as a thickness of the second alignment key.

11. The method of claim 9, wherein the forming of the second alignment key comprises forming the second alignment key on a scribe lane of the second surface.

12. The method of claim 9, wherein the forming of the second alignment key comprises forming the second alignment key in a cylindrical shape or a rectangular parallelepiped shape.

13. The method of claim 9, wherein the forming of the second alignment key comprises forming the second alignment key at a position corresponding to the first alignment key.

14. The method of claim 9, wherein the coating of the lower insulating layer comprises coating the second surface with an epoxy resin, polybenzobisoxazole (PBO), benzocyclobutene (BCB), polyimide (PI), and/or a polyimide derivative.

15. The method of claim 9, wherein the coating of the lower insulating layer comprises coating the lower insulating layer on the second surface with a thickness of about 3 micrometers to about 10 micrometers.

16. The method of claim 9, further comprising cutting the interposer substrate, wherein the cutting of the interposer substrate comprises cutting the interposer substrate along a portion having the second alignment key.

17. A method of manufacturing a semiconductor package, the method comprising:
manufacturing an interposer;
mounting the interposer on a circuit board;
mounting a semiconductor chip on the interposer; and
forming an encapsulation material for molding the interposer and the semiconductor chip,
wherein the manufacturing of the interposer comprises:
disposing a lower insulating layer on a second surface opposite to a first surface of an interposer substrate;
aligning a first alignment key on the first surface with a first photomask;
patterning the lower insulating layer with the first photomask to form a lower circuit pattern and a second alignment key on the second surface;
forming a lower metal layer on the lower insulating layer; and
aligning the second alignment key with a second photomask and patterning a photoresist layer on the lower metal layer to expose the lower circuit pattern using the second photomask.

18. The method of claim 17, further comprising forming a connection terminal on the lower circuit pattern,
wherein the forming the lower circuit pattern and the second alignment key comprises:
patterning the lower insulating layer using the first photomask to simultaneously form the lower circuit pattern and the second alignment key,
wherein a thickness of the lower insulating layer is the same as a thickness of the second alignment key.

19. The method of claim 17, wherein the mounting of the interposer on the circuit board comprises aligning the interposer with the circuit board by using the first alignment key and/or the second alignment key.

20. The method of claim 17, further comprising:
cutting the encapsulation material and exposing an upper surface of the semiconductor chip; and
attaching a heat sink to the upper part of the semiconductor chip.
